(19) United States
(12) Patent Application Publication
(10) Pub. No.: US 2008/0237754 A1
(43) Pub. Date: Oct. 2, 2008

(54) System, methods and apparatuses for nanoelectronics applied to nanorobots

(75) Inventor: Neal Solomon, Oakland, CA (US)

Correspondence Address: Neal Solomon, P.O. Box 21297, Oakland, CA, 94620, US

(73) Assignee: Solomon Research LLC, Oakland, CA (US)

(21) Appl. No.: 11/985,078

(22) Filed: Nov. 13, 2007

Related U.S. Application Data
(60) Provisional application No. 60/865,605, filed on Nov. 13, 2006.

(51) Int. Cl. H01L 27/14

(52) U.S. Cl. 257/414; 257/499; 257/E27.122

(57) ABSTRACT

A nanorobotic apparatus is described consisting of hybrid MEMS and NEMS components. The nanorobot contains sensors for situational awareness. The apparatus has nanofilament components for communications.

### CROSS-REFERENCES TO RELATED APPLICATIONS

The present application claims the benefit of priority under 35 U.S.C. § 119 from U.S. Provisional Patent Application Ser. No. 60/865,605, filed on Nov. 13, 2006, the disclosures of which are hereby incorporated by reference in their entirety for all purposes.

### FIELD OF THE INVENTION

The present invention pertains to the field of nanotechnology and nanorobotics. The system deals with epigenetic robotics applied to collectives of nanorobots. Specifically, the invention relates to nanoelectromechanical systems (NEMS) and microelectromechanical systems (MEMS), nanomechatronics and bionanomechatronics. The invention also deals with the coordination of collectives of nanorobots, synthetic nanorobotics and synthetic bionanorobotics, including synthetic assemblies of NEMS and nanorobots and synthetic nano-scale and micron-scale machine assembly processes.

### BACKGROUND OF THE INVENTION

To date, four waves, or generations, of nanotechnology have evolved. The first generation was comprised mainly of developments involving chemical composition, such as new nanomaterials. The second generation developed simple tubes and filaments by positioning atoms from the ground up with novel machinery. The third generation developed nanodevices that perform specific functions, such as nanoparticles for the delivery of chemicals. Finally, the fourth wave has developed self-assembling nanoentities by chemical means.

The present invention represents a fifth generation of self-organizing collectives of intelligent nanorobotics. Self-organizing processes are possible at the nano- and micron-level because of the convergence of nanoelectronics developments and nanomechatronics developments.

While the first four generations of nanotechnology have been developed by theoretical scientists and inventors, the fifth generation of nanotechnology has been largely open until now. The present invention fills the gaps in the literature and in the prior art involving nanorobotics.

Early twentieth century theoretical physicists discovered that the simplest atoms were measurable at the nanometer scale of one billionth of a meter. In 1959, in his lecture “Race to the Bottom,” the physicist Richard Feynman proposed a new science and technology to manipulate molecules at the nanoscale. In the 1970s Drexler's pioneering research into nanotechnology molecular-scale machinery provides a foundation for current research. In 1979, researchers at IBM developed scanning tunneling microscopy (STM) with which they manipulated atoms to spell the letters IBM. Also in the 1970s Ratner and his team at Northwestern developed the first nano-scale transistor-like device for nanoelectronics, which was developed into nanotransistors by researchers at the University of Californnia at Berkeley in 1997. Researchers at Rice, Yale and Penn State were able to connect blocks of nanodevices and nanowires, while researchers at Hewlett Packard and UCLA were able to develop a computer memory system based on nano-assembly. Additionally, government researchers at NASA, NIST, DARPA and Naval Research have ongoing nanotechnology development projects, though these are mainly focused on nanoelectronics challenges. Finally, researchers at MIT, Cal Tech, USC, SUNY, Cornell, Maryland, Illinois and other universities in the U.S. have been joined by overseas researchers in developing novel nanotechnologies in order to meet Feynman's challenge.

Nanotech start-up ventures have sprung up to develop nanoscale crystals, to use as biological labels, for use in tagging proteins and nucleic acids (Quantum Dot) and to develop micro-scale arms and grippers by using MEMS to assemble manufacturing devices (Zyvex). Additionally, Nanosys, Nanometrics, Ultatech, Molecular Electronics, Applied Nanotech and Nanorex are ventures that have emerged to develop products in the nanotechnology market space. Until now, however, most of these businesses have focused on inorganic nanomaterials. Though a new generation of materials science has been aided by these earlier generations of nanotechnologies, the real breakthrough lies in identifying methods of developing intelligent systems at the nano-scale.

The two main models for building nanotechnology applications are the ground up method of building entities, on the one hand, and the bottom down method of shrinking photolithography techniques to the nanoscale. Both models present challenges for scientists.

In the case of the bottom up models, several specialized tools have been required. These include (a) atomic force microscopy (AFM), which uses electronics to measure the force exerted on a probe tip as it moves along a surface, (b) scanning tunneling microscopy (STM), which measures electrical current flowing between a scanning tip and a surface, (c) magnetic force microscopy (MFM), which uses a magnetic tip that scans a surface and (d) nanoscale synthesis (NSL), which constructs nanospheres.

In the case of the top down models, several methods and techniques have been developed, including (a) x-ray lithography, (b) ion beam lithography, (c) dip pen nanolithography (DPN), in which a “reservoir of ‘ink’ (atoms/molecules) is stored on top of the scanning probe tip, which is manipulated across the surface, leaving lines and patterns behind” (Ratner, 2003) and (d) micro-imprint lithography (MIL), which emulates a rubber stamp. Lithography techniques generally require the creation of a mask of a main model, which is then reproduced onto a substrate much like a semiconductor is manufactured. It is primarily through lithographic techniques that mass quantities of nanoentities can be created efficiently and cost-effectively.

The main patents obtained in the U.S. in the field of nanotechnology have focused on nanomaterials, MEMS, micro-pumps, micro-sensors, micro-voltaics, lithography, genetic microarray analysis and nano-drug delivery. Examples of these include a meso-microelectromechanical system package (U.S. Pat. No. 6,859,119), micro-opto-electro-mechanical systems (MOEMS) (U.S. Pat. No. 6,580,858), ion beam lithography system (U.S. Pat. No. 6,924,493), carbon nanotube sensors (U.S. Pat. No. 7,013,708) and microfabricated elastomeric valve and pump systems (U.S. Pat. Nos. 6,899,137 and 6,929,030). Finally, patents for a drug targeting system (U.S. Pat. No. 7,025,991) and for a design of artificial genes for use as controls in gene expression analytical system (U.S. Pat. No. 6,943,242), used for a DNA microarray, are applied to biotechnology. For the most part, these patents represent third and fourth generation nanotechnologies.

A new generation of nanotechnologies presents procedures for objects to interact with their environment and solve critical problems on the nano- and micron-scale. This generation of technology involves social intelligence and self-organization capabilities.

Biological analogies help to explain the performance of intelligent or self-organizing nanoentities. In the macro-scale environment, the behaviors of insects provides an important model for understanding how to develop models that emulate social intelligence in which chemical markers (pheromones) are used by individual entities to communicate a social goal. On the micro-scale, microbes and pathogens interoperate with the animal's immune system, in which battles either won or lost determine survival of the host. Other intracellular models show how proteins interact in order to perform a host of functions. At the level of DNA, RNA transcription processes are highly organized methods for developing cellular reproduction. These micromachinery processes and functions occur at the nanoscale and provide useful analogies for nanotechnologies.

In order to draw on these biological system analogies, complexity theory has been developed in recent years. Researchers associated with the Sante Fe Institute have developed a range of theoretical models to merge complexity theory and biologically-inspired processes, including genetic algorithms and collective behavior of economic agents.

Such a new nanotechnology requires distributed computation and communication techniques. It is, moreover, necessary for such a technology to adapt to feedback from its environment. The present invention presents a system in which these operations occur and specifies a range of important applications for electronics, medicine and numerous other areas. The main challenges to this advanced nanotechnology system lie in the discovery of solutions to the problems of limited information, computation, memory, communication, mobility and power.

Challenges

The development of a fifth generation of nanotechnologies faces several challenges. First, the manufacturing of nanoparts is difficult. Second, the assembly of nanoparts into functional devices is a major challenge. Third, the control and management of nanosystems is complex. Since physical properties operate differently at the nano-scale than at the macro-scale, we need to design systems that accommodate these unique physical forces.

The problems to identify include how to:
Build nanorobots
Connect nanodevices
Develop a nanorobotic power source
Develop nanorobotic computation
Develop specific nanorobotic functionality
Develop nanorobotic communication system(s)
Develop multi-functional nanorobotics
Activate nanorobotic functionality
Develop nanorobotic computer programming
Develop an external tracking procedure for a nanorobot
Develop an external activation of a nanorobot
Develop a hybrid control system for nanorobots
Use AI for nanorobots
Obtain environmental inputs via sensors

Developing Solutions to these Problems

Most prior technological innovations for nano-scale problems have focused on the first generations of nanotechnology and on materials science. The next generation focuses on intelligent systems applied to the nano entities. This fifth generation of innovation combines the development of nano-scale entities with intelligence of complex systems.

Few researchers have devised solutions to these complex nano-scale problems. Cavalcanti has developed theoretical notions to develop a model of nanorobotics. However, these solutions are not practical and will not work in real situations. For example, there is not enough power of mobility in this model to overcome natural forces. Similarly, according to this theoretical approach, autonomous computation resources of nanorobots are insufficient to perform even the simplest functions, such as targeting. Without computation capacity, AI will not work at this level; without AI there is no possible way to perform real-time environmental reaction and interaction.

Cavalcanti's 2D and 3D simulations are dependent on only several variable assumptions and will not withstand the “chaos” of real environmental interactive processes. In addition, the structure of these nanorobots cannot be built efficiently from the bottom up and still retain critical functionality. Even if these many problems can be solved, individual nanorobots cannot be trusted to behave without error inside cells.

The emerging field of epigenetic robotics deals with the relations between a robot and its environment. This field suggests that it is useful to program a robot to learn autonomously by interacting with its environment. However, these models do not apply to groups of robots in which it is necessary to learn from and interact with many more variables in the robots' environment, including societies of other robots. In the case of groups of nanorobots with resource constraints, the present invention adds volumes to this promising field.

Solomon's research in developing hybrid control systems for robotic systems and in developing novel approaches for molecular modeling systems presents pathways to solving these complex problems. These novel research streams are used in the present invention.

Prior systems of robotics generally do not address the complexities of nanotechnology. The behavior-based robot system using subsumption methods developed by Brooks at MIT is useful for managing individual robot behavior with limited computation capacity. On the other end of the spectrum, central control robotic systems require substantial computation resources. Hybrid control robotic systems synthesize elements from these two main control processes. Even more advanced robotic control systems involve the integration of a multi-agent software system with a robotic system that is particularly useful in controlling groups of robots. This advanced robotic control system experiences both the benefits and detriments of the behavior-based model and the central control model.

The Nanorobotic Environment

The nano domain, which is a billionth of a meter, is measured in millionths of a meter. A single oxygen atom is roughly a single nanometer across. A micron is a millionth of a meter. The width of a human hair is about 60,000 nanometers.

The present invention focuses on the synthetic development of objects that are in a middle (meso-nano) sphere somewhat between the atomic size (micro-nano) of simple atoms and the mega-nano domain of micron-sized objects. While it is true that scientists have built, from the ground up, that is, atom by atom, objects such as elegant geodesic nanotubes made of carbon atoms, objects in this domain are too small and too expensive to construct to be useful for an active intelligent system. In order to be useful, a nanorobotic system requires numerous and economical robots dependent on mass production techniques that must generally be considered from the perspective of a top down strategy, that is, by utilization of largely lithographic procedures.

The nanorobotic entities described herein generally consist of objects with dimensions from 100 nm to 1000 nm (1 micron) cubed, but can be smaller than 100 nm or larger than ten microns. This size is relatively large by nanotechnology standards, but is crucial in order to maintain functionality. Keep in mind that a white blood cell is comprised of about 100,000 molecules and fits into this meso-nano domain. The micron-scale space of inter-object interaction may be comprehended by analogy to a warehouse in which nanoscale objects interact. In order to be useful, nanorobots require complex apparatus that includes computation, communications, sensors, actuators, power source and specific functionality, all of which apparatus requires spatial extension. Though this domain specification is larger than some of the atomic-scale research in nanotechnology, it is far smaller than most microelectronics.

While the larger meso-nano assemblies described herein possess a specific geometric dimensionality, the size dimensions of the domains in which they operate are also critical to consider. In these cases, each application has a different set of specifications. In the case of the human body, specific cells will have a dimensionality that is substantially larger than the complex molecular-size proteins that are constructed for interoperation within them.

Over time, however, it will be possible to make very small, useful micro-nano scale robots for use in intelligent systems. Thus, we may conceive of several generations of scale for these systems, the first being in the meso-nano domain.

### SUMMARY OF THE INVENTION

Nanorobots possess specific functionality. These distinctive functions consist of sensor capacity (often organized into networks), storage, pump assembly for chemical transport and so on. There are multifunctional nanorobots as well, comprised of larger assemblies and possessing greater utility. The single-functional nanorobots increase functionality when teamed with other specialists. However, the larger the assembly of nanorobot, the more useful it generally will be.

Simple single-capacity nanorobots contain a simpler computation resource system, such as an ASIC, while more sophisticated multifunctional nanorobots will have more complex computers such as a microprocessor, FPGA or hybrid circuitry. The main challenge is to develop ways to combine functionality, design and computation capacity in a unified and integrated nanorobotic package. The problem is compounded by the need to design multiple types of nanorobotic systems that will coordinate behaviors of multiple nanorobotic specialists.

Specific procedures that collectives of nanorobots will perform include: targeting, payload delivery, data gathering, social learning, memory pooling, computation sharing, aggregation and reaggregation.

Nanorobots communicate in different ways. First, they communicate by line-of-site, much as a driver would see a neighboring car next to, ahead of, or behind it. Second, they communicate using chemical means, like leaving “breadcrumb” traces (in ant algorithms). Third, they communicate in an omninodal way with wireless mechanisms, typically using radio frequency (RF) signals; most CNR processes use this communications model for optimal effect. Finally, they communicate between the nanorobots and an external location. One way for the external source to communicate with the nanorobots is to broadcast messages to the entire group.

A main problem with wireless communications processes is that the environment is noisy and therefore signal completion is intermittent. Low power is another complicating factor affecting communications capacity. Consequently, it is necessary to continuously attempt to send and retrieve messages, with constantly updatable messages whenever possible. When the system, or subsets of the main system, is accessible, it is necessary to obtain the newest programming or instructions. While broadcasting instructions may be effective, it is also necessary to provide messages to specific nanorobots at key times, which is only possible using short-range RF wireless mechanisms. Because of these constraints, it is necessary to use nanorobots to pass messages between one another within the communications network. The network passes messages from node-to-node as needed in order to optimize the efficiency of limited resources.

In order to promote the communications between nanorobots, it is necessary for each nanorobot to include, along with its computation capacity, a nanofilament antenna. Beyond this simple communication apparatus, nanorobots are combined to create an antennae array that will be effective for this purpose; in fact, by so aligning the nanorobots, the range of communication signals is increased.

In addition to communication functions, it is necessary to track the nanorobotic collective. This can be accomplished by tagging and tracking each nanorobot's positions, much like a GPS signal tracking system coordinates a position by triangulating a location. However, this can also be done by using localized beam radar or sonar processes. Finally, the nanorobots in a CNR may send signals to an external location semi-continuously. To provide accurate information on CNR activities, it is necessary to track the nanorobots in four dimensions so that they reveal their precise locations in real time.

Once the nanorobotics are tracked, complex modeling processes must be developed. These modeling processes are generally performed with sufficient external computation resources. These active modeling processes involve accurately mapping the strategies and behaviors of the nanorobots. Maps are created and constantly updated to accommodate the changing behavior of the nanorobots. As new information, such as the identification of anomalies, is transmitted from the nanorobots to the external computer resources, the map is constantly updated.

### DESCRIPTION OF THE INVENTION

There are several main domain categories in which nanorobots will operate. These include the surface of a solid in nanoelectronic systems. In the electronic sphere, it is generally possible to control the environment.

In general, the micro-nano domain (at the atomic level) is subject to quantum mechanical rules of operation of objects, including wavelet vibrations, electron leakage and other behaviors that are not typical at the macro-scale. Key natural forces such as heat, electromagnetic forces and atomic and molecular forces become prominent. Atoms move at this level like syrup. The spinning motions of atoms, particularly as they are excited, can create a distinctive effect, such as a funnel vortex or a tornado. Friction is also a prominent force that limits the functionality of objects at the nano-scale.

It is important to use these distinctive physical attributes at the nano-scale to advantage. For example, using the atomic and molecular forces makes it possible to reduce the energy needed to manipulate these forces. In another example, it is possible to use these attractive atomic or molecular forces as a sort of “glue” to bind robotic parts. It is also possible to harness repulsive atomic forces to break nano-scale objects apart. The challenge is to create system procedures to oscillate between attractive and repulsive forces in order to achieve specific functional objectives.

Heat conductivity at the nano-scale creates the need for specific techniques to dissipate heat, including use of a silicon nitride nanobridge or a Coulomb island (conductor coupled to a nanocircuit). A trade-off in the structure of a nanodevice is needed so that it can conduct energy efficiently as well as dissipate heat. This is why some nanomaterials require techniques that activate them with bursts of heat, light or electrical current. In other cases, crystalline nanoparticles require specific energy inputs in order to activate a process such as evaporation or conductance.

Ultimately, nanorobots need to operate without degradation in a range of media that includes air, the surface of solid materials and complex and variable fluids.

One challenge for nanorobotic systems is the construction of methods of mobility. In addition to using environmental forces to the benefit of a productive goal, it is necessary to create autonomous mobility in nanorobots. This internal power is typically furnished by a nano-scale motor that runs on various energy sources such as electrical or solar power. Optimally, the internal motor of a nanorobot provides self-generation capabilities. Alternatively, internal nanorobotic motors may be powered with heat or wireless beams of light. Without autonomous mobility or power, the functionality of a nanorobot is limited to the constraints of mobility in the specific environment.

Collectives of nanorobots are able to use collective power. Larger nanorobots, for instance, will be able to carry or push smaller nanorobots. In some cases, the nanorobots will share power sources for optimal effect.

Nanoelectronics

There are several types of nanoelectronics systems. These consist of nanoelectromechanical system (NEMS) parts in nanoelectronic systems as well as hybrid NEMS and microelectromechanical systems (MEMS) such as traditional micron-scale semiconductors. NEMS sensors and communications interfaces integrate into MEMS apparatus as well. A fully developed NEMS apparatus such as a semiconductor integrates into NEMS or MEMS mechanical apparatuses such as a functional nano- or micro-robot. Finally, nanoparts are integrated into optical sensors. The following descriptions discuss these novel applications of nanotechnology using aspects of the present system.

(1) NEMS Apparatus in NEMS Robotic Assembly

A nanorobot contains elements of nanoelectronics, such as a system on a chip (SoC) semiconductor device, within a larger structural casing. The nanoelectronic system includes computer logic circuits (whether a microprocessor, an ASIC, a ZISC, an FPGA or a quantum computer along with analog-to-digital and digital-to-analog converters) and memory circuits. These electronic components are connected to other nanoelectronic parts, including a communications system (consisting of a processing element and antennae for wire or wireless transmission and reception), sensor(s), an actuator, a motor, a power source and specific on-board mechanical or electromechanical parts that confer specific functionality, such as gears, shielding, cargo space, valves or pumps.

The nanoelectronics computer components are fabricated independently of the NEMS structural components and then integrated by using assembly techniques. Alternatively, the entire apparatus may be manufactured as a single integrated unit. The present invention creates the integrated circuit device components using top down lithographic techniques and integrates this assembly with structural components using either top down or bottom up nanoconstruction techniques. In some ways, the decreased size limit is constrained by the functional capacity of the computing platform. It is therefore expected that while initially this computer system will likely be in the mega-nano scale initially, over time, it will likely shrink to the meso-nano scale, or about 100 nm to 1 micron.

(2) Hybrid MEMS and NEMS

The present system integrates NEMS parts into MEMS robotic structures. NEMS components, such as nano-scale chip sets, are integrated into MEMS assemblies as microelectronic systems become increasingly smaller. It is not unusual, then, to have NEMS parts integrate with other systems, including not only microelectronics but photonic systems and mechanical systems as well. Optoelectronic systems require NEMS parts as their utility involves ever smaller components.

An example of this system integration is the use of nanofilaments in MEMS communications devices in which the filaments provide simple RF antennae or nanoelectronic parts such as nanotransistors. Similarly, nanooptoelectronic mechanical (NOEMS) systems are integrated with MEMS assemblies in order to maximize the benefits of both.

(3) NEMS Sensors in MEMS Controllers for Environmental Feedback Mechanism

Since mobility is a key factor in nanorobotics, the use of nanoscale sensors becomes increasingly important. Nanosensor systems are integrated into MEMS assemblies in order to obtain environmental feedback by using MEMS controllers. Image sensors and optical-digital sensors are used by mechanical devices for machine vision. The use of nanosensor arrays in MEMS assemblies produces adaptive mechanisms in stationary or mobile systems.

Use of NEMS sensor arrays in stationary distributed networks of microelectronic mechanical systems substantially enhances MEMS networks. When NEMS sensor arrays are used in mobile distributed MEMS networks, the system becomes adaptive. Plasticity processes are evident in adjustable and evolvable interactive strategies in which feedback mechanisms become part of the system dynamics. With a NEMS sensor network integrated into a MEMS system, continuous “vision” of, and full data access to, the environment is facilitated.

(4) NEMS Communication Interface

The NEMS communication interface may be either hard-wired or wireless. While it is possible for a communication interface to use nanofilaments hardwired to an electronic system, a wireless communications system is optimal for improved mobility. Line of sight systems require complex optoelectronic apparatuses that may be unreliable, particularly in bionano domains.

In a NEMS communication interface, communications signals are sent from a nanorobot at regular intervals. This provides two purposes. First, it allows intermittent signals to be sent from a nanorobot to other locations, either other nanorobots or an external location. Second, it provides a tool to track the location of the nanorobot back to its signal even as the location of the nanorobot changes. In this last capacity, the intermittent signaling behaves as a beacon.

(5) Nano-RF Repeaters for Communications

Because communications resource constraints are significant at the nano-scale, nanorobots require distinctive architectures. Nanorobots have a limited communication range, which makes the use of a distributed system of groups of nanorobots critical when specific nanorobots communicate at a limited range to their closest neighbor. Although such distributed network architectures use node-to-node message passing procedures, it is still necessary to amplify communications signals in this distributed nanorobotic system.

The present system provides a novel way to bounce signals from position to position so as to extend the range of a signal. The system involves the use of nanorobots as repeaters to temporarily amplify and bounce communication signals beyond the range of a single node. For instance, when a series of nanorobots is arranged in a sequence of nodes, the nanorobots successively receive and retransmit the signal to their neighbors. Because the system is mobile, in some cases the nanorobots will temporarily rearrange geometric position (by using mobility) precisely in order to behave as a repeater assembly system so as to transmit signals.

These techniques are critical in effectively surpassing nanoscale limits of communication due to limited power, transmission and reception capabilities. Ultimately, a critical mass of nanorobots will pool resources, by using a cumulative threshold of a large quantity of nanorobots, to send or receive signals wirelessly. This procedure is used to transmit and receive signals from the collective and to an external source as well as vice versa.

Reference to the remaining portions of the specification, including the drawings and claims, will realize other features and advantages of the present invention. Further features and advantages of the present invention, as well as the structure and operation of various embodiments of the present invention, are described in detail below with respect to accompanying drawings.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference for all purposes in their entirety.

### DESCRIPTION OF THE DRAWINGS

FIG. 1 is a block diagram of a nanorobot.

FIG. 2 is a block diagram of a three dimensional representation of a nanorobot with sensors.

FIG. 3 is a block diagram of a three dimensional representation of a nanorobot with communications components.

FIG. 4 is a block diagram of a supplemental power source attached to a nanorobot apparatus.

FIG. 5 is a schematic diagram of three nanorobots in a communication system.

FIG. 6 is a schematic diagram of a three dimensional nanorobot with communications components.

FIG. 7 is a schematic diagram of multiple nanorobots linked to a central apparatus.

FIG. 8 is a schematic diagram of multiple nanorobots attached to a three dimensional apparatus.

FIG. 9 is a schematic diagram of a linear apparatus connecting mobile nanorobots.

### DETAILED DESCRIPTION OF THE DRAWINGS

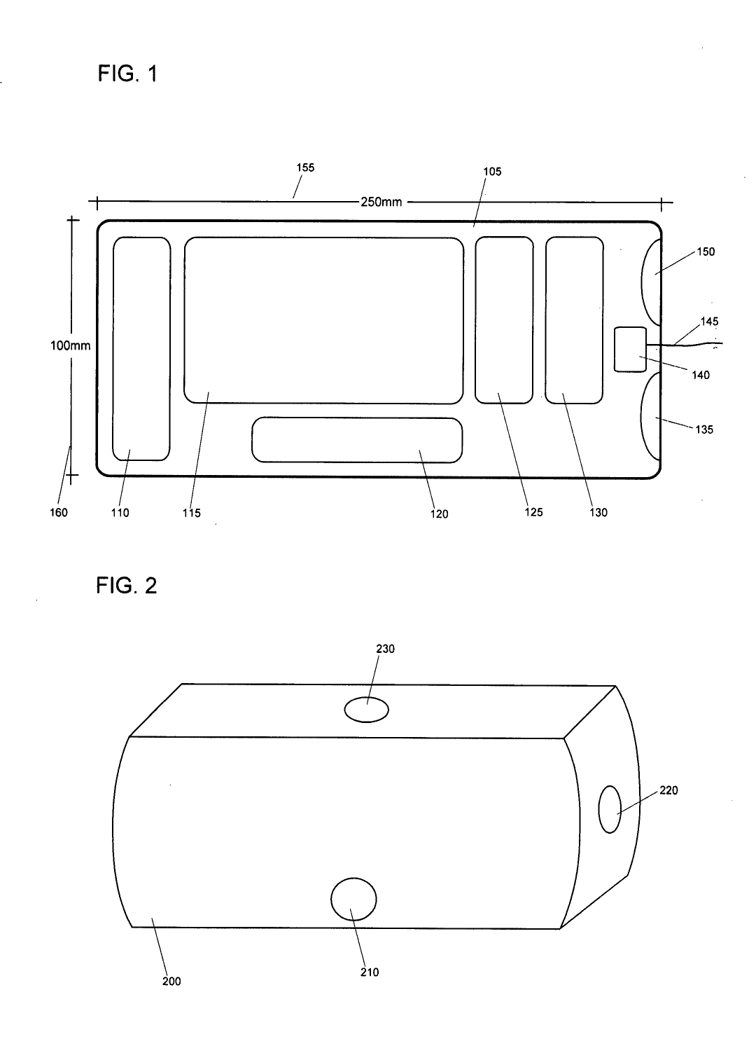

FIG. 1 illustrates the components of a nanorobot (105). The motor is identified (at 110), the semiconductor (at 115), the power source (at 120), the computer memory (at 125), the actuator (at 130), the sensors (at 135 and 150) and the communications interface (at 140). The nanofilament is shown (at 145) connected to the communications interface. In one embodiment, the integrated circuit (semiconductor) is integrated with computer memory and the communications interface. In another embodiment, the motor is integrated with the power source and the actuator. The integration of these components maximizes efficiency and functionality. This block representation of the nanorobot is not intended to limit its configuration options, which may appear as round (such as plates) or spheres (geodesic) or modular aerodynamic configurations.

Though the nanorobotic dimensions are specified as 250 nm (at 155) long and 100 nm (at 160) high, the nanorobotic apparatus may be smaller or longer. Similarly, the depth of the device may be variable. In some embodiments, the nanorobotic device will have variable dimensions.

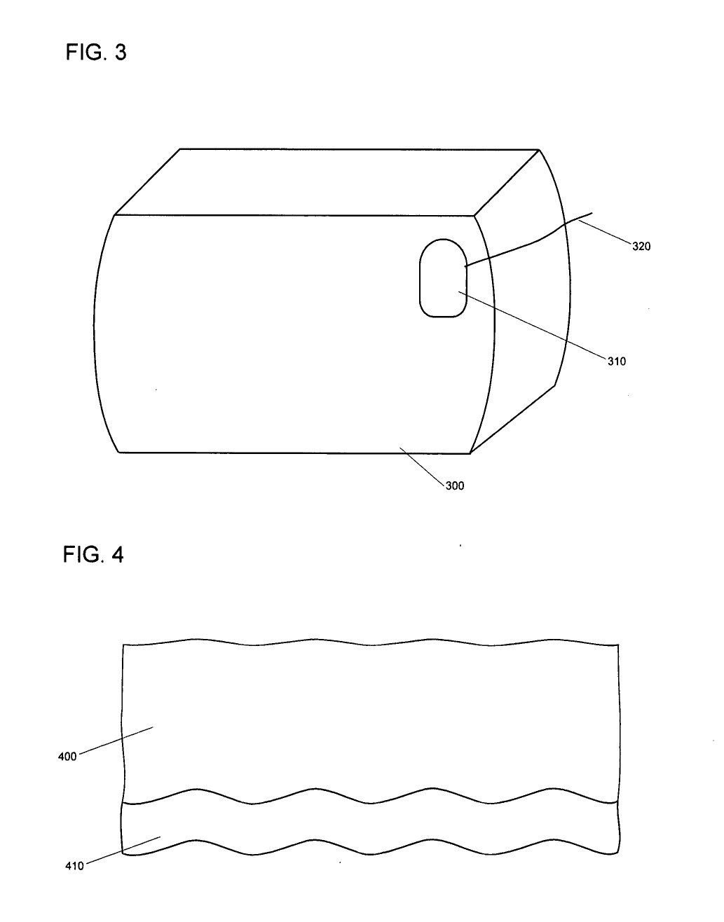

In FIG. 2, the nanorobotic device (200) is shown to have sensors on different planes (at 210, 220 and 230). FIG. 3 shows the nanorobot (300) with the communications interface (310). Connected to the communications interface is a nanofilament (320), which acts as an antennae for sending and receiving signals.

One main constraint for nanorobots is the availability and use of power supplies. In FIG. 4, the nanorobot (400) has a supplemental power supply (410) that is affixed to it. After the power supply is used, it is either recharged by another apparatus or it is detached and another fully charged power supply attached.

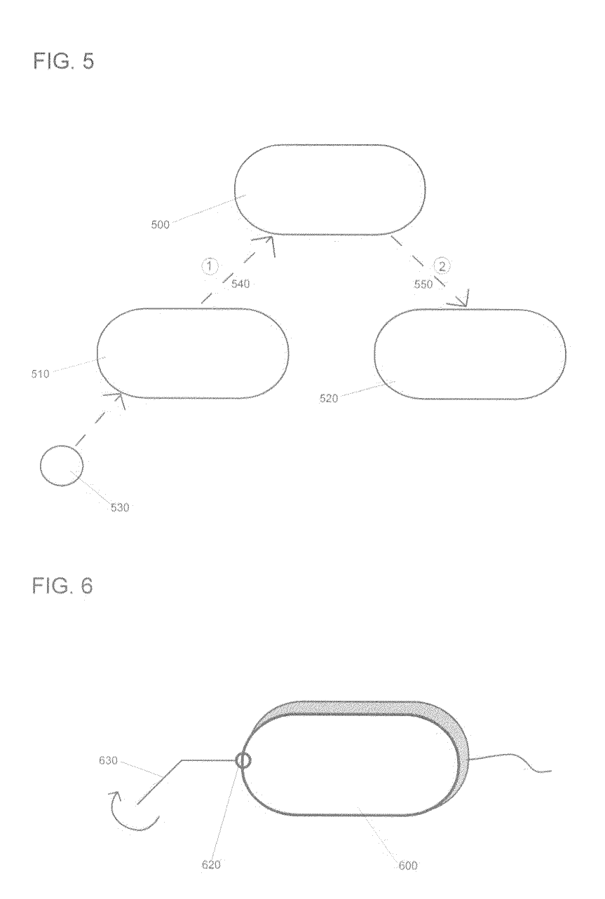

The challenge of communications between nanorobots is significant. In FIG. 5, three nanorobots are shown (500, 510 and 520). When the nanorobot at 510 encounters an object (530), it sends a message (540) to the nanorobot at 500. After it receives a message about the object, the nanorobot at 500 sends a message (550) to the nanorobot at 520. In this way, groups of nanorobots will communicate directly to each other. Communications capability between nanorobots provides the elements of social intelligence that allow functionality beyond nearest neighbor behavior control.

The communications devices use nanofilaments, an example of which is shown in FIG. 6 at 630. The nanofilament is flexible in order to maximize the communications signal reception by employing a swivel joint (620).

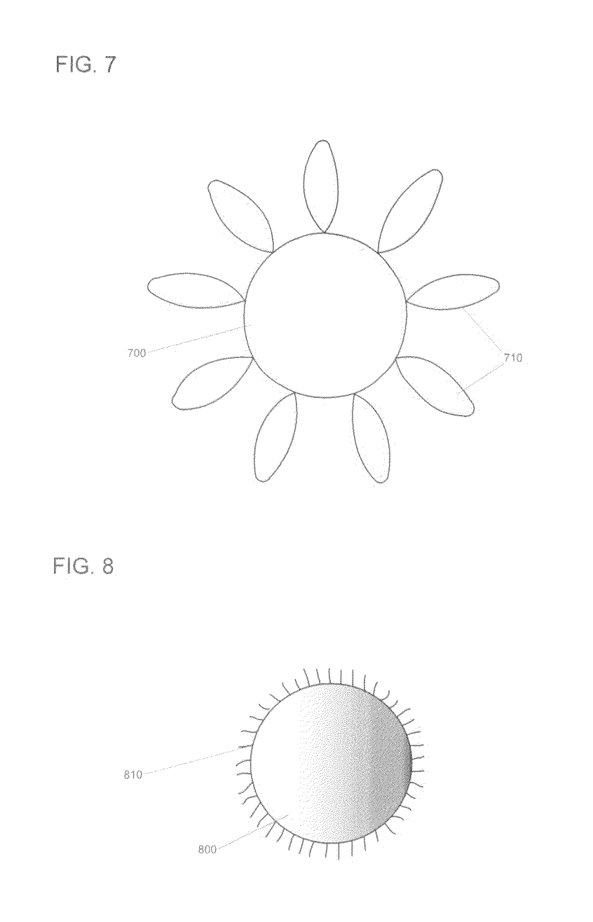

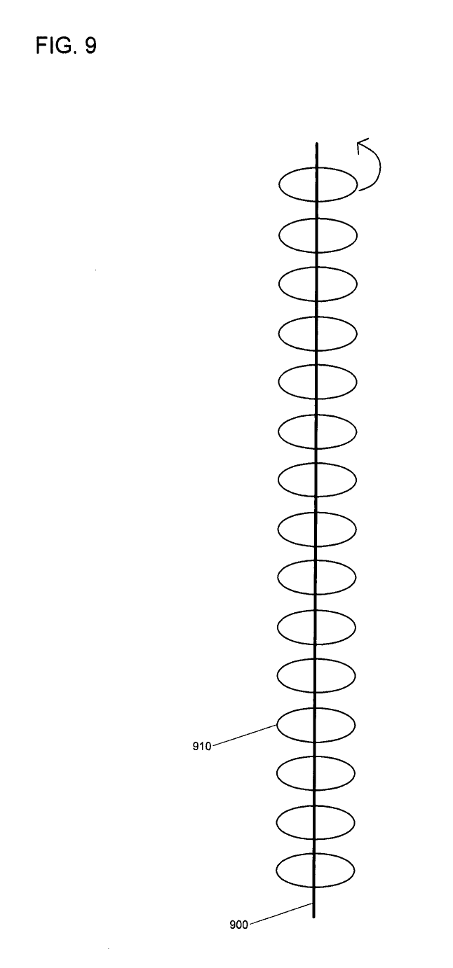

FIGS. 7 and 8 show multiple nanorobotic devices aggregated to centralized devices. The central device, shown in FIG. 7 in two dimensions (700) and FIG. 8 in three dimensions (800) has numerous nanorobots (710 and 810, respectively) attached to them. The central devices are used as energy sources and as central bases from which the nanorobots will depart and return when on specific missions.

As shown in FIG. 9, the nanorobots will align on a linear device (900) which aligns multiple nanorobots. The nanorobots will move around the axis of the line in order to adjust their positions.

What is claimed is:

1. A system for integrating nanoelectronic components in a nanorobot device, comprising:
a nano-scale integrated circuit with nano-scale computer memory,
a nano-scale sensor,
a nano-scale communications device comprised of nanofilaments,
a nano-scale actuator;
a nano-scale power supply;
a structural casing;
wherein the nanorobot device contains the nano-scale elements;
wherein the nanorobot device has a functional utility;
wherein the nanorobot device has mobility;
wherein the nanorobot device uses computational functionality to analyze sensor data and adjust position;
wherein the nanorobotic device contains components to attach and detach from other nanorobot devices; and
wherein the nanorobot device uses communications functionality to send and receive signals.

2. A system for nanorobotic sensors, comprising:
nano electro mechanical system (NEMS) sensors;
wherein the NEMS sensors are structured in arrays;
wherein the NEMS sensors feed data to a nanorobotic integrated circuit;
wherein the nanorobotic integrated circuit provides feedback to the NEMS sensors to maintain sensor data; and
wherein the NEMS sensor arrays are optical-digital.

3. A system for nanorobot communications, comprising:
nano filaments that act as antennae for the nanorobot device;
a communications interface to send and receive signals;
an integrated circuit that analyzes sensor data and communications signals;
the nanorobots have mobility
wherein the nanofilaments behave as repeaters to move the communications signals between nanorobot devices;
wherein the nanorobot device emits signals intermittently to emulate a beacon;
wherein the nanorobotics signals are sent wirelessly;
wherein the nanorobotics signals are received wirelessly; and
wherein the nanorobot mobility allows the nanorobot to modulate the signal to optimize its reception or transmission.
